(19) United States
(12) Patent Application Publication
(10) Pub. No.: US 2021/0238730 A1
(43) Pub. Date: Aug. 5, 2021

(54) Evaporation Boat

(71) Applicant: Kennametal Inc., Latrobe, PA (US)

(72) Inventor: Alexander Draken, Perlesreut (DE)

(21) Appl. No.: 17/162,486

(22) Filed: Jan. 29, 2021

(30) Foreign Application Priority Data
Jan. 31, 2020 (DE) 102020102483.5

(51) Int. Cl. C23C 14/24

(52) U.S. Cl. CPC C23C 14/243; C23C 14/26

(57) ABSTRACT

An evaporation boat comprising an evaporation body that extends along an axis of rotation (D) and has a rotational symmetry about the axis of rotation (D) with an index count of at least 3. The evaporation body in this case has a number of evaporation sides that corresponds to the index count of the rotational symmetry.

### RELATED APPLICATION DATA

The present application claims priority pursuant to 35 U.S.C. § 119(a) to German Patent Application 102020102483.5 filed Jan. 31, 2020, which is incorporated herein by reference in its entirety.

### FIELD

The invention relates to an evaporation boat with an evaporation body that extends along an axis of rotation.

### BACKGROUND

Evaporation boats are known and are typically used in equipment for coating substrates, wherein they are provided in a vacuum chamber to provide a metal vapor that is deposited as a thin homogeneous layer on the substrate. In order to provide a constant vapor flow, evaporation boats are heated in a direct electrical current flow to such an extent that an infed metal wire, e.g., an aluminum wire, is liquefied on an evaporation side of the evaporation boat and subsequently vaporized at the low air pressure present in the vacuum chamber. The evaporation side in this case holds and heats up the molten metal of the metal to be evaporated until the molten metal evaporates.

At the location where the evaporation boat is in direct contact with the molten metal, the evaporation boat is subject to heavy corrosion that limits the tool life of the evaporation boat. In order to reliably ensure a constant vapor flow, evaporation boats typically need to be replaced after about 15 operating hours.

The task of the invention is to provide an evaporation boat that has a longer tool life and that is designed for material efficiency.

### SUMMARY

This task is solved by providing an evaporation boat with an evaporation body that extends lengthwise along an axis of rotation and has a rotational symmetry about the axis of rotation with an index count of at least 3. The evaporation body in this case has a number of evaporation sides that corresponds to the index count of the rotational symmetry. For purposes of the invention, an evaporation side in this case is a side of the evaporation body that is provided to accommodate and/or hold the molten metal of the metal to be evaporated when the evaporation boat is in use.

This design allows using the evaporation boat in various positions, wherein a different evaporation side is respectively used as the active evaporation side to liquefy and hold the metal to be evaporated. As a result, the evaporation boat is an indexable evaporation boat whose different evaporation sides are selected as active evaporation sides by rotating the evaporation boat about its axis of rotation and bringing it into the corresponding position. By operating the evaporation boat in the various positions, the evaporation boat has a longer total tool life as compared to conventional evaporation boats from the prior art.

The rotational symmetry ensures that the core of the evaporation body through which the axis of rotation extends has a sufficiently large cross-section and/or has sufficient mass such that the corroded region of an evaporation side does not significantly impair the respectively other evaporation sides, as is for example the case for conventional evaporation bodies with a rectangular cross section, on which the corroded region of the evaporation side extends so far into the core that the tool life of the evaporation boat cannot be significantly increased by indexing the evaporation boat and using the opposing side as the evaporation side.

The rotational symmetry of the evaporation body furthermore has the advantage that the evaporation body has a particularly compact and therefore material-efficient design.

For purposes of the invention, the rotational symmetry in particular relates to the basic shape of the evaporation body so that markings to differentiate the evaporation sides or embossed part numbers can be omitted for the evaporation boat, and therefore cannot impair the rotational symmetry.

In one embodiment, the evaporation body has a rotational symmetry about the axis of rotation with an index count of 3, 4, 5, or 6 as this can achieve a particularly good relationship of tool life to material input and manufacturing effort for the evaporation boat.

The evaporation boat can also have a total rotational symmetry about the axis of rotation with an index count of at least 3, in particular of 3, 4, 5, or 6, so that the evaporation boat can be manufactured particularly efficiently in terms of material and cost.

Analogously to the evaporation body, the rotational symmetry for purposes of the invention likewise relates to the basic shape of the evaporation boat so that markings to differentiate the evaporation sides or part numbers can be waived for the evaporation boat and can therefore not impair the rotational symmetry.

In a further embodiment, each evaporation side comprises a receiver cavity. For purposes of the invention, receiver cavities are cavities designed to hold the molten metal of the metal to be evaporated when the evaporation boat is in use.

It is advantageous when the evaporation boat has two clamping ends at opposite axial ends, wherein the evaporation body extends lengthwise between these along the axis of rotation. Using the clamping ends, the evaporation boat can be reliably clamped into a corresponding toolholder in a defined manner, in particular between two copper clamps.

It can be provided in this case that the clamping ends do not extend radially beyond the evaporation sides and/or their enclosed ends in relation to the axis of rotation. The clamping ends in this case have a different cross-sectional geometry than the evaporation bodies, in particular in the axial section of the evaporation body that abuts the respective clamping end. The clamping ends can as a result have an efficient design in terms of material.

Each clamping end can also have an assigned clamping surface for each evaporation side. Every clamping surface in this case extends parallel to a plane that is formed by the associated evaporation side. Every clamping surface and the associated evaporation side are in this case additionally arranged opposing each other in relation to the axis of rotation. In this manner, each clamping surface forms a horizontal contact surface by which the evaporation boat can make contact to a tool holder, in particular a holding clamp, so that the evaporation boat can be securely held in a position assigned to the respective evaporation side.

It can be provided in this case that each clamping end has an opposing upper side for each clamping surface, the upper side transitioning in a planar manner to the surface of the evaporation side that is assigned to the corresponding clamping surface. This allows the evaporation boat to be manufactured with particularly low effort.

According to an embodiment, the clamping surfaces are formed by bevels that are formed in axial edges of the clamping end. The clamping surfaces can as a result be manufactured particularly cost-effectively.

According to a further embodiment, the evaporation boat can be heated as an electrical resistance heater by direct electrical current flow. The evaporation boat in this case in particular consists of a material having a sufficiently high resistance. This has the advantage that the temperature of the evaporation boat can be controlled very accurately by applying an electrical voltage.

### BRIEF DESCRIPTION OF THE DRAWINGS

Further advantages and features can be found in the following description in conjunction with the attached drawings. The drawings show:

FIG. 1. In a perspective rendering, an evaporation boat according to the invention with a rotational symmetry index count of three,

FIG. 2. In a side view, the evaporation boat from FIG. 1,

FIG. 3. In a cross-section rendering along the cross-section line III-III in FIG. 2, the evaporation boat from FIG. 1,

FIG. 4. In a schematical rendering, a cross-section of the evaporation boat from FIG. 1 in a corroded state, and

FIG. 5. In a schematical rendering, a cross-section of a conventional evaporation boat with a rectangular cross section in a corroded state.

### DETAILED DESCRIPTION

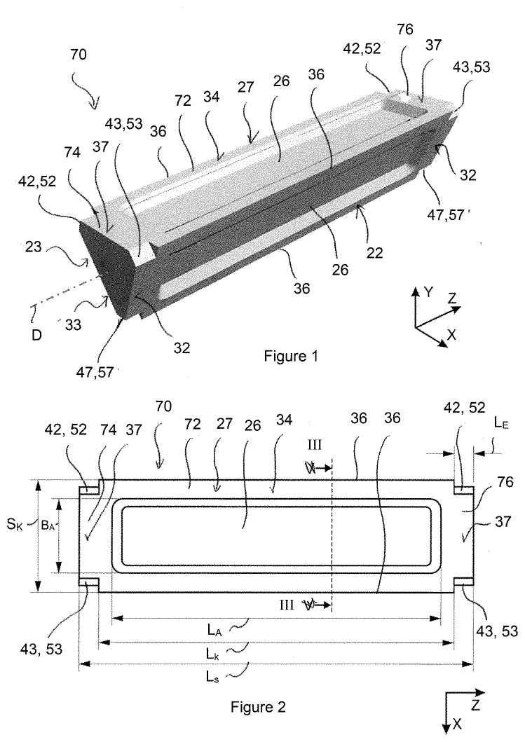

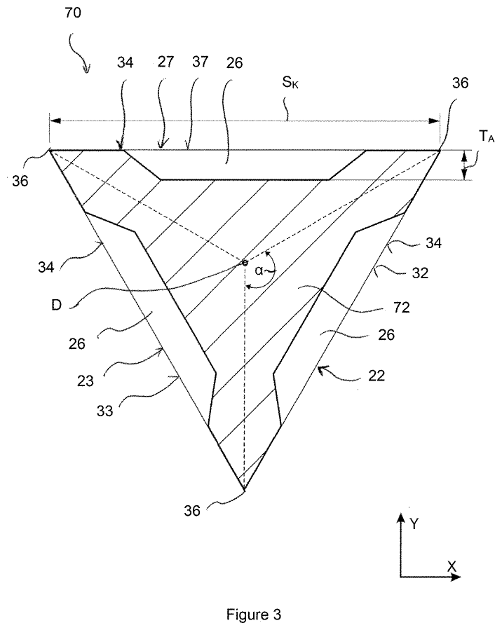

FIGS. 1 and 2 show an evaporation boat 10 that extends along an axis of rotation D and has an evaporation body 12 and a first clamping end 14 and a second clamping end 16 that abut as a single piece in axial direction Z on the axial faces of the evaporation body 12.

The evaporation boat 10 also has a rotationally symmetrical design with respect to the axis of rotation D.

In the shown embodiment, the evaporation boat 10 can be rotated three times about the axis of rotation D at an angle α of 120° (see FIG. 3), wherein each rotation results in a representation of the evaporation boat 10 onto itself. This means that the evaporation boat 10 has a rotational symmetry about the axis of rotation D with an index count of 3.

Hence, each individual axial section of the evaporation boat 10 has the same rotational symmetry about the axis of rotation.

In an alternative embodiment, the evaporation body 12 can have a rotationally symmetrical design about the axis of rotation D, whereas the first and the second clamping end 14, 16 can have an arbitrary design.

The evaporation boat 10 has the basic shape of a cylinder with an equilateral triangle as the basic surface.

Mathematics also describes such a body as a regular prism, e.g., a straight prism with a regular polygon as the basic surface.

In an alternative embodiment, the evaporation body 12 can have the basic shape of a regular prism, whereas the first and the second clamping end 14, 16 can have an arbitrary design.

The evaporation boat 10 has three evaporation sides 21, 22, 23 formed by the three sides of the evaporation body 12 that form the outer surface of the evaporation body 12.

The evaporation body 12, in particular the entire evaporation boat 10, can principally have an arbitrary rotational symmetry about the axis of rotation D with an index count of at least 3.

For example, the evaporation body 12, in particular the entire evaporation boat 10, can have a rotational symmetry about the axis of rotation D with an index count of 4 and a basic shape in the form of a straight prism having a square as the basic surface and an angle α of 90°; a rotational symmetry about the axis of rotation D with an index count of 5 and a basic shape in the form of a straight prism with a regular pentagon as a basic surface and an angle α of 72°; or a rotational symmetry about the axis of rotation D with an index count of 6 and a basic shape in the form of a straight prism with a regular hexagon as a basic shape and an angle α of 60°.

In all cases, the evaporation body 12 has a number of evaporation sides 21, 22, 23, that corresponds to the index count of the rotational symmetry about the axis of rotation D.

In the shown exemplary embodiment, each evaporation side 21, 22, 23 has a receiver cavity 26.

The receiver cavities 26 in this case form recesses in the basic shape of the evaporation body 12. In the area of the receiver cavities 26, the evaporation body 12 correspondingly has a cross-section (see FIG. 3) in the form of an equilateral triangle with corresponding recesses due to the receiver cavities 26.

In an alternative embodiment, the evaporation body 12 can have a design without receiver cavities 26.

In particular, the evaporation sites 21, 22, 23 are in this case planar.

The first clamping end 14 and the second clamping end 16 have an identical design. The shape of the two clamping ends 14, 16 is discussed as follows based on examples for the first clamping end 14.

In an alternative embodiment, the first clamping end 14 and the second clamping end 16 can of course have a design that differs from each other.

In the shown embodiment, the clamping end 14 has the same basic shape as the abutting evaporation body 12, that is to say a cylinder with an equilateral triangle as the basic shape.

The sides that form the outer surface of the cylinder in this case each form an upper side 31, 32, 33 of the clamping end 14 that transitions in a planar manner into the surface 34 of the abutting evaporation side 21, 22, 23 of the evaporation body 12.

In contrast to the axial edges 36 of the evaporation body 12, the axial edges of the clamping end 14 are formed as bevels 41, 42, 43.

The bevels 41, 42, 43 can be designed as continuous bevels or as stepped bevels.

In an alternative embodiment, the axial edges 36 of the evaporation body 12 can also be formed as bevels so that the bevels 41, 42, 43 of the clamping ends 14, 16 extend over the entire axial length of the evaporation boat 10.

The bevels 41, 42, 43 in this case each form a clamping surface 51, 52, 53 that is assigned to the respectively opposing evaporation side 21, 22, 23 and extends parallel to the side of the basic shape of the evaporation body 12 that forms the corresponding evaporation side 21, 22, 23. In this manner, an evaporation side 21, 22, 23 is oriented horizontally when the evaporation boat 10 makes planar contact on a horizontal holding surface of a tool holder, e.g., the surface of a holding clamp, with the clamping surface 51, 52, 53 assigned to the corresponding evaporation side 21, 22, 23.

In an alternative embodiment, the clamping surfaces 51, 52, 53 or even the clamping ends 14, 16 can principally have an arbitrary design.

On an evaporation boat 10 with an even number of evaporation sides 21, 22, 23, the clamping surfaces 51, 52, 53 can at the same time form the upper sides 31, 32, 33 of the clamping ends 14, 16.

In a particularly straightforward embodiment, the evaporation boat 10 is a cuboid having a square basic surface and 4 evaporation sides that are formed by the rectangular side surfaces of the cuboid.

The evaporation boat 10 can act as an electrical heating resistor and can consist of a corresponding material, and can then be heated by applying an electrical voltage by way of direct current flow.

Due to the rotationally symmetrical design of the evaporation body 12, the evaporation boat 10 can be used in three different positions to evaporate metal, wherein a different evaporation side 21, 22, 23 is used for evaporating in each position.

In the present exemplary embodiment, the evaporation body 12 has a side length S_{K} of 30 mm and an axial length L_{K} of 118 mm.

The receiver cavities 26 each have a width B_{A} of 24 mm, an axial length L_{A} of 110 mm, and a depth T_{A} of 3 mm.

The evaporation boat 10 has an axial length L_{S} of 130 mm, wherein each clamping end 14, 16 has an axial length L_{E} of 6 mm.

The evaporation boat 10, the evaporation body 12, the receiver cavities 26, and the clamping ends 14, 16 can of course have arbitrary dimensions in an alternative embodiment.

In an alternative embodiment, the evaporation body 12 can in particular have a side length S_{K} from 20 mm to 40 mm.

Based on the aforementioned dimensions, each evaporation side 21, 22, 23 of the evaporation boat 10 can be used for approximately 10 hours to evaporate metal so that the tool life of the evaporation boat 10 is about 30 hours.

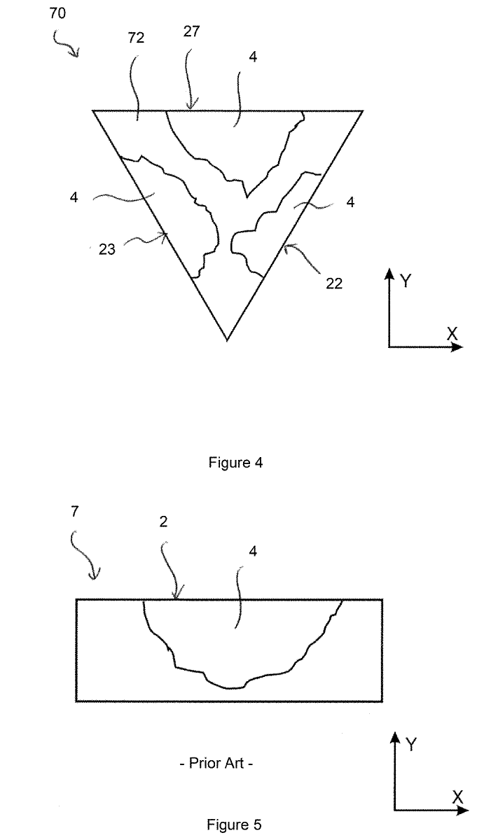

By rotating the evaporation boat 10 about the axis of rotation D after 10 operating hours each from an already used evaporation side 21, 22, 23 to a not yet used evaporation side 21, 22, 23, the corroded areas K (see FIG. 4) that result when evaporating metal can be distributed over the cross-section of the evaporation body 12, thus achieving an increased tool life.

In comparison thereto, a conventional evaporation boat 1 (see FIG. 5) having a rectangular cross-section and an evaporation side 2 while having the same cross-sectional area as the evaporation body 12 of the evaporation boat 10 only has a tool life of about 15 hours before the corroded area K renders the conventional evaporation boat 1 unusable.

In this manner, the tool life can be doubled with the evaporation boat 10 at a comparable cross-sectional area and therefore comparable material input.

The rotationally symmetrical design of the evaporation body 12 and/or the evaporation boat 10 also has the advantage that the evaporation boat 10 can be produced cost-effectively.

The rotationally symmetrical design of the evaporation body 12 furthermore ensures that all evaporation sides 21, 22, 23 are identical and have the same properties for evaporating metal.

As a result, the evaporation boat 10 can in particular be operated in all positions, e.g., using all evaporation sides 21, 22, 23 in the same manner when in operation, without having to significantly modify the tool holder for the evaporation boat 10 and/or the voltage for heating the evaporation boat 10.

The invention is not limited to the embodiment shown. In particular, individual features of an embodiment can be arbitrarily combined with the features of other embodiments, in particular independently of the other features of the respective embodiments.

1. An evaporation boat comprising an evaporation body that extends lengthwise along an axis of rotation (D), wherein the evaporation body has a rotational symmetry about the axis of rotation (D) with an index count of at least 3, wherein the evaporation body has a number of evaporation sides that corresponds to the index count of the rotational symmetry.

2. The evaporation boat according to claim 1, wherein the evaporation body has a rotational symmetry about the axis of rotation (D) with an index count of 4, 5, or 6.

3. The evaporation boat according to claim 2, wherein the evaporation boat has a rotational symmetry about the axis of rotation (D) with an index count of 5 or 6.

4. The evaporation boat according to claim 1, wherein each evaporation side has a receiver cavity.

5. The evaporation boat according to claim 1, wherein the evaporation boat comprises two clamping ends on opposite axial ends, between which the evaporation body extends lengthwise along the axis of rotation (D).

6. The evaporation boat according to claim 5, wherein the clamping ends do not extend radially beyond the evaporation sides in relation to the axis of rotation (D), and wherein the clamping ends have a cross-sectional geometry different from the evaporation body.

7. The evaporation boat according to claim 5, wherein each clamping end has an assigned clamping surface for each evaporation side, wherein each clamping surface extends parallel to a plane that is formed by the associated evaporation side, wherein each clamping surface and the associated evaporation side are assigned opposite to each other in relation to the axis of rotation (D).

8. The evaporation boat according to claim 7, wherein each clamping end has an opposing upper side for each clamping surface that transitions in a planar manner into the surface (34) of the particular evaporation side that is assigned to the corresponding clamping surface.

9. The evaporation boat according to claim 7, wherein the clamping surfaces are formed by bevels.

10. The evaporation boat according to claim 1, wherein the evaporation boat can be heated by direct current flow, and comprises a material that has an electrical resistance.
